(19) United States
(12) Patent Application Publication
(10) Pub. No.: US 2025/0349548 A1
(43) Pub. Date: Nov. 13, 2025

(54) METHOD, SYSTEM AND APPARATUS FOR FORMING METAL-INSULATOR-METAL AND/OR METAL-FERROELECTRIC-METAL DEVICE

(71) Applicant: ASM IP Holding B.V., Almere (NL)

(72) Inventors: Jessica Akemi Cimada da Silva, Chandler, AZ (US); Fu Tang, Gilbert, AZ (US); Rohit Abraham John, Chandler, AZ (US); Alessandra Leonhardt, Sipoo (FI); Andrea Illiberi, Leuven (BE)

(21) Appl. No.: 19/200,826

(22) Filed: May 7, 2025

Related U.S. Application Data
(60) Provisional application No. 63/645,727, filed on May 10, 2024.

(51) Int. Cl. H01L 21/285; C23C 16/455; H01L 21/324

(52) U.S. Cl. CPC H01L 21/28556; C23C 16/45553; H01L 21/2855; H01L 21/324

(57) ABSTRACT

A method, system and apparatus for depositing a composite film, comprising, supporting a substrate, depositing a first metal electrode via a first non-Atomic Layer Deposition (non-ALD) process, depositing a first metal liner, via a first cyclic ALD process, depositing a dielectric layer comprising a first crystalline structure, via a second cyclic ALD process, wherein the dielectric layer is in physical contact with the first metal liner layer and at least in electrical communication with the first metal electrode, inducing a first in-plane tensile stress in the dielectric layer at a first interface between the first metal liner and the dielectric layer and converting the first crystalline structure to a second crystalline structure, responsive to the first in-plane tensile stress.

### CROSS-REFERENCE TO RELATED APPLICATIONS

This application is a nonprovisional of, and claims priority to and the benefit of, U.S. Provisional Patent Application No. 63/645,727, filed May 10, 2024 and entitled “METHOD, SYSTEM AND APPARATUS FOR FORMING METAL-INSULATOR-METAL AND/OR METAL-FERROELECTRIC-METAL DEVICE,” which is hereby incorporated by reference herein.

### FIELD OF INVENTION

The present disclosure generally relates to methods, systems and apparatus suitable for forming one or more layers on a surface of a substrate and to structures including the one or more layers. More particularly, the disclosure relates to methods, systems and apparatus for forming layers of semiconductor devices including Metal-Insulator-Metal (MIM) and Metal-Ferroelectric-Metal (MFM) devices.

### BACKGROUND OF THE DISCLOSURE

In semiconductor fabrication, the ongoing trend of device miniaturization is propelled by the demand for enhanced performance, reduced power consumption, and greater integration density. This miniaturization presents certain challenges in the production of Metal-Insulator-Metal (MIM) and Metal-Ferroelectric-Metal (MFM) devices, which utilize high-k dielectrics or ferroelectric materials. These materials are chosen for their superior electrical characteristics, such as high capacitance and non-volatility, essential for device functionality. However, as the industry advances towards nodes smaller than 10 nm, the implementation of these materials becomes increasingly complex.

A significant hurdle is the development of materials with sufficient high-k or ferroelectric properties. The reduction in dielectric thickness necessary for device scaling complicates the preservation of these properties within the constraints of a low thermal budget, which is a critical consideration in many practical applications. Additionally, conventional methods to enhance the quality of high-k or ferroelectric materials may not be viable for mass production due to their time-intensive nature, complexity, intricacy and cost, making them less feasible for widespread manufacturing. Thus, there is an urgent need for innovative manufacturing techniques that can produce advanced semiconductor devices at large scale while maintaining high-quality electrical properties, complying with stringent thermal budgets, and remaining cost-effective for high-volume production.

### SUMMARY OF THE DISCLOSURE

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

In one aspect, disclosed herein are a methods, systems and apparatus for depositing a composite film, comprising supporting a substrate, depositing a first metal electrode via a first non-Atomic Layer Deposition (non-ALD) process, depositing a first metal liner, via a first cyclic ALD process, depositing a dielectric layer via a second cyclic ALD process, the dielectric layer disposed in electrical communication with the first metal electrode and in physical contact with the first metal liner, wherein the dielectric layer may comprise a first crystalline form, inducing a first in-plane tensile stress in the dielectric layer at a first interface between the first metal liner and the dielectric layer, and converting the first crystalline form to a second crystalline form, responsive to the first in-plane tensile stress.

In certain examples, the dielectric layer may be a high-k material or a ferroelectric material. In various examples, the depositing the first metal liner may be performed at a temperature in a range of 150° C.-600° C. In particular examples, the first metal liner may be deposited on a surface of the dielectric layer. In some examples, the first crystalline form may be in a first non-centrosymmetric state and the second crystalline form may be in a second non-centrosymmetric state.

In some examples, the second non-centrosymmetric state may comprise greater non-centrosymmetricity than the first non-centrosymmetric state. In examples of the disclosed technology, at least a portion of the first crystalline form may be in an amorphous phase and the second crystalline form may be in a crystalline orthorhombic phase or to a crystalline tetragonal phase, or a combination thereof. In certain examples, the first crystalline form may comprise a first percentage of a crystalline orthorhombic phase and the second crystalline form may comprise a second percentage of the crystalline orthorhombic phase, wherein the second percentage may be greater than the first percentage. In particular examples, the converting the first crystalline form to the second crystalline form further may comprise heating the dielectric layer to a temperature in a range of 150° C. to 700° C. In various examples, the method may further comprise exposing the substrate to one or more transformation treatments comprising at least one of a rapid thermal anneal, an anneal treatment, a plasma treatment, or exposure to ozone, or a combination thereof. In some examples, the converting the first crystalline form to the second crystalline form further may comprise exposing the substrate to a transformation treatment comprising at least one of a rapid thermal anneal (RTA), an anneal, a plasma exposure, an ozone exposure, an oxidizing agent exposure, a nitridation agent exposure, a reducing agent exposure, or an inert gas exposure, or a combination thereof. In certain examples, the converting the first crystalline form to the second crystalline form increases a dielectric constant of the dielectric layer by 10%-100%. In examples of the disclosed technology, the converting the first crystalline form to the second crystalline form increases a ferroelectricity of the dielectric layer. In various examples, the non-ALD process may comprise a chemical vapor deposition (CVD) or a physical vapor deposition (PVD) process. In some examples, the tensile stress induced by the first metal liner may be greater than the tensile stress induced by the first metal electrode.

In particular examples, the first cyclic ALD process may comprise: a) contacting the substrate with a first vapor phase precursor, b) contacting the substrate with a second vapor phase precursor, c) purging the chamber, and repeating one or more of operations a), b) or c), or a combination thereof, in any order, until the first metal liner having a first predetermined thickness may be deposited on the substrate. In certain examples, the first vapor phase precursor may comprise at least one of titanium tetrachloride (TiCl4), titanium tetraiodide (TiI4), titanium tetrabromide (TiBr3), tantalum pentachloride (TaCl5) or a combination thereof. In various examples, the second vapor phase precursor may comprise at least one of ammonia (NH3), hydrazine (N2H4), a hydrazine derivative, an alkyl-hydrazine, tertbutylhydrazine (C4H9N2H3), methylhydrazine (CH3NHNH2), dimethylhydrazine ((CH3)2N2H2), phenylhydrazine, tert-butylamine, isobutylamine, tert-pentylamine, N2 plasma, N2/H2 plasma, NH3 plasma, an excited species of nitrogen, nitrogen ions, nitrogen radicals, or a combination thereof. In certain examples, the first metal liner may comprise titanium nitride (TiN) or tantalum nitride (TaN). In examples of the disclosed technology, the first cyclic ALD process further may comprise: d) contacting the substrate with an oxygen reactant, and repeating one or more of operations a), b), c) or d), or a combination thereof, in any order, until the first metal liner having the first predetermined thickness may be deposited on the substrate. In certain examples, the first metal liner may comprise titanium oxynitride. In some examples, the first metal electrode may comprise a top metal electrode and the first metal liner may comprise a top metal liner comprising a metal nitride, wherein the depositing the first metal liner, further may comprise disposing the top metal liner in physical contact with the top metal electrode and depositing a second metal electrode via a second non-Atomic Layer Deposition (non-ALD) process, wherein the second metal electrode may comprise a bottom metal electrode in physical contact with the dielectric layer. In particular examples, the bottom metal electrode and the top metal electrode are each less than 50 nanometers (nm) in thickness and wherein the top metal liner may be less than 100 angstrom (Å) in thickness. In various examples, the first metal electrode may comprise a bottom metal electrode and the first metal liner may comprise a bottom metal liner, and wherein the depositing the first metal liner further may comprise disposing the bottom metal liner in physical contact with the bottom metal electrode. In various examples, further comprising depositing a second metal electrode via a second non-Atomic Layer Deposition (non-ALD) process, wherein the second metal electrode may comprise a top metal electrode in physical contact with the dielectric layer. In certain examples, the bottom metal electrode and the top metal electrode are less than 50 nanometers (nm) in thickness and wherein the bottom metal liner may be less than 100 angstrom (Å) in thickness.

In examples of the disclosed technology, the second cyclic ALD process may comprise: e) contacting the substrate with a third vapor phase precursor, f) contacting the substrate with a fourth vapor phase precursor, g) contacting the substrate with an oxygen reactant, h) purging the reaction chamber, and repeating one or more operations e), f) g), or h) or any combination thereof, in any order, until the dielectric layer having a predetermined thickness may be deposited on the substrate. In various examples, the third vapor phase precursor may comprise at least one of: tetrakis(dimethylamino)hafnium, tetrakis(diethylamino)hafnium, tetrakis(ethylmethylamino)hafnium, HfCl4, HfBr4, and HfI4, tetrakis(dimethylamino)zirconium (TDMAZ), tetrakis(dimethylamido)titanium (TDMAT), hafnium tetra-tert-butoxide (Hf(OC(CH3)3)4), tetrakis-ethylmethylaminosilane (Si(N(CH3)—(C2H5))4), trimethylaluminum (TMA), tris (N,N′-diisopropylacetamidinato) yttrium (III) (Y(DPfAMD)3), Ge(NMe2)4, Ge(OnBu)4, tris(N, N′-diisopropylacetamidinato) cerium (III) (Ce(DPfAMD)3), tris(N, N′-diisopropylacetamidinato)yttrium (III) (Y(DPfAMD)3), tantalum pentachloride (TaCl5), scandium chloride (ScCl3), bismuth chloride (BiCl3), or a combination thereof. In certain examples, the fourth vapor phase precursor may comprise at least one of: tetrakis (dimethylamino) zirconium, tetrakis (diethylamino) zirconium, tetrakis-ethylmethylaminosilane (Si(N(CH3)—(C2H5))4) or tetrakis (ethylmethylamino) zirconium, or any combination thereof. In various examples, the oxygen reactant may be one or more of H2O, H2O2, O2, O3, N2O, NO, NO2 or an oxygen plasma. In certain examples, the dielectric layer may comprise a dielectric material comprising at least one of: hafnium oxide (HfO2), hafnium zirconium oxide (HZO), zirconium oxide (ZrO2), titanium oxide (TiOx), hafnium silicate (HfSiOx), aluminum oxide (Al2O3), lanthanum oxide (La2O3), germanium oxide (GeOx), cerium oxide (CeOx), yttrium oxide (YxOy), tantalum oxide (TaxOy), scandium oxide (ScxOy), bismuth oxide (BixOy), one or more of the dielectric materials doped with yttrium oxide, or combinations thereof. In various examples the method may further comprise: depositing a second metal liner via a third cyclic ALD process, wherein the second metal liner may comprise a top metal liner in physical contact with the dielectric layer, inducing a second in-plane tensile stress in the dielectric layer at a second interface between the top metal liner and the dielectric layer, depositing a second metal electrode via a non-Atomic Layer Deposition (non-ALD) process, wherein the second metal electrode may comprise a top metal electrode in physical contact with the top metal liner.

In examples of the disclosed technology, the third cyclic ALD process may comprise: i) contacting the substrate with a fifth vapor phase precursor, j) contacting the substrate with a sixth vapor phase precursor, k) purging the reaction chamber, and repeating one or more operations i), j) or k), or any combination thereof, in any order, until the second metal liner having a third predetermined thickness may be deposited on the dielectric layer. In particular examples, the fifth vapor phase precursor may comprise at least one of titanium tetrachloride (TiCl4), titanium tetraiodide (TiI4), titanium tetrabromide (TiBr3), tantalum pentachloride (TaCl5) or a combination thereof. In various examples, the sixth vapor phase precursor may comprise at least one of ammonia (NH3), hydrazine (N2H4), a hydrazine derivative, an alkyl-hydrazine, tertbutylhydrazine (C4H9N2H3), methylhydrazine (CH3NHNH2), dimethylhydrazine ((CH3)2N2H2), phenylhydrazine, tert-butylamine, isobutylamine, tert-pentylamine, N2 plasma, N2/H2 plasma, NH3 plasma, an excited species of nitrogen, nitrogen ions, nitrogen radicals, or any combination thereof. In some examples, the second metal liner may comprise titanium nitride (TiN) or tantalum nitride (TaN). In examples of the disclosed technology, the third cyclic ALD process further may comprise: l) contacting the substrate with the oxygen reactant, and repeating one or more operations i), j), k) or l), or a combination thereof, in any order, until the second metal liner having the third predetermined thickness may be deposited on the dielectric layer. In particular examples, the second metal liner may comprise titanium oxynitride (TiON). In certain examples, the bottom metal electrode and the top metal electrode are less than 50 nanometers (nm) in thickness and wherein the top metal liner and the bottom metal liner are less than 100 angstrom (Å) in thickness.

In various examples, the composite film, forms at least a portion of a Metal-Insulator-Metal (MIM) structure, a Metal-Ferroelectric-Metal (MFM) structure, a Ferroelectric Random Access Memory (FeRAM) structure, a Ferroelectric Field-Effect Transistor (FeFET) structure, a Dynamic Random-Access Memory (DRAM) structure, a Resistive Random-Access Memory (ReRAM) structure or an Embedded Dynamic Random-Access Memory (eDRAM) structure, or a combination thereof.

For purposes of summarizing the invention and the advantages achieved over the prior art, certain objects and advantages of the invention have been described herein above. Of course, it is to be understood that not necessarily all such objects or advantages may be achieved in accordance with any particular example of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these examples are intended to be within the scope of the invention herein disclosed. These and other examples will become readily apparent to those skilled in the art from the following detailed description of certain examples having reference to the attached figures, the invention not being limited to any particular example(s) disclosed.

### BRIEF DESCRIPTION OF THE DRAWING FIGURES

While the specification concludes with claims particularly pointing out and distinctly claiming what are regarded as examples of the invention, the advantages of examples of the disclosure may be more readily ascertained from the description of certain examples of the examples of the disclosure when read in conjunction with the accompanying drawings, in which:

FIG. 1 illustrates a schematic diagram of a reactor system, in accordance with examples of the present technology.

FIG. 2 illustrates a schematic diagram of a reactor system having multiple reaction chambers, in accordance with examples of the present technology.

FIGS. 3A-3C illustrate exemplary structures in accordance with examples of the present technology.

FIG. 4A illustrates an example process for depositing a composite film, in accordance with examples of the present technology.

FIG. 4B illustrates an example cyclic ALD process, in accordance with examples of the present technology.

FIG. 4C illustrates an example cyclic ALD process, in accordance with examples of the present technology.

FIG. 4D illustrates an example cyclic ALD process, in accordance with examples of the present technology.

FIG. 4E illustrates an example non-ALD deposition process, in accordance with examples of the present technology.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The detailed description of various examples herein makes reference to the accompanying drawings, which show the exemplary examples by way of illustration. While these exemplary examples are described in sufficient detail to enable those skilled in the art to practice the disclosure, it should be understood that other examples may be realized and that logical, chemical, and/or mechanical changes may be made without departing from the spirit and scope of the disclosure. Thus, the detailed description herein is presented for purposes of illustration only and not of limitation. For example, the steps recited in any of the method or process descriptions can be executed in any combination and/or order and are not limited to the combination and/or order presented. Further, one or more steps from one of the disclosed methods or processes can be combined with one or more steps from another of the disclosed methods or processes in any suitable combination and/or order. Moreover, any of the functions or steps can be outsourced to or performed by one or more third parties. Furthermore, any reference to singular includes plural examples, and any reference to more than one component can include a singular example.

Although certain examples are disclosed below, it will be understood by those in the art that the disclosure extends beyond the specifically disclosed examples and/or uses of the disclosure and obvious modifications and equivalents thereof. Thus, it is intended that the scope of the disclosure should not be limited by the particular examples described herein.

The illustrations presented herein are not meant to be actual views of any particular material, apparatus, structure, or device, but are merely representations that are used to describe examples of the disclosure.

As used herein, the term “substrate” can refer to any underlying material or materials that may be used, or upon which, a device, a circuit, or a film/layer may be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material.

As used herein, the term “atomic layer deposition” (ALD) can refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) can subsequently be introduced into the process chamber for use in converting the chemisorbed precursor to the desired material on the deposition surface. Typically, this reactant is capable of further reaction with the precursor. Further, purging steps can also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) can refer to any process wherein a substrate is exposed to one or more volatile precursors, which react and/or decompose on a substrate surface to produce a desired deposition.

As used herein, the term “cyclic deposition” may refer to the sequential introduction of one or more precursors and/or reactants into a reaction chamber to deposit a film over a substrate and includes deposition techniques such as atomic layer deposition and cyclic chemical vapor deposition.

As used herein, the terms “layer,” “film,” and/or “thin film” can refer to any continuous or non-continuous structures and material deposited by the methods disclosed herein. For example, “layer,” “film,” and/or “thin film” could include 2D materials, nanorods, nanotubes, or nanoparticles or even partial or full molecular layers or partial or full atomic layers or clusters of atoms and/or molecules. “Layer,” “film,” and/or “thin film” can comprise material or a layer with pinholes, but still be at least partially continuous.

A number of example materials are given throughout the examples of the current disclosure, it should be noted that the chemical formulas given for each of the example materials should not be construed as limiting and that the non-limiting example materials given should not be limited by a given example stoichiometry.

Further, in this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, or the like. Further, in this disclosure, the terms “including,” “constituted by” and “having” can refer independently to “typically or broadly comprising,” “comprising,” “consisting essentially of,” or “consisting of” in some examples. In this disclosure, any defined meanings do not necessarily exclude ordinary and customary meanings in some examples.

As noted above, high volume manufacturing of semiconductor devices having materials with sufficient high-k or ferroelectric properties presents a significant challenge in light of industry drive toward miniaturization.

Disclosed herein are methods, systems, and apparatus for depositing a composite film compatible with a variety of semiconductor devices (e.g., MIM and MFM devices) having high-k or ferroelectric properties and reduce dimensions that may be applied in high-volume fabrication.

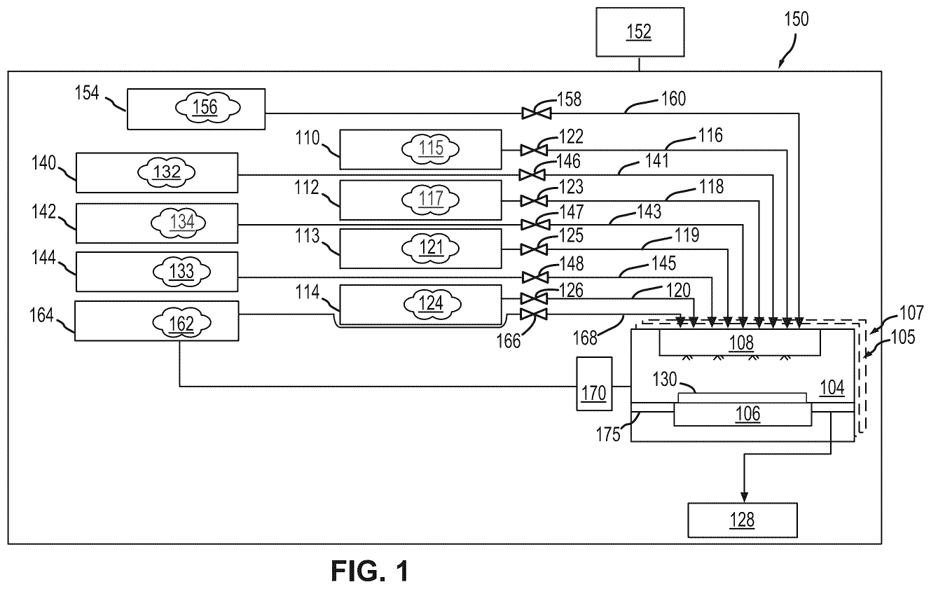

FIG. 1 is a schematic illustration representing an abstraction of an example reactor system 150. Reactor system 150 may comprise one or more reaction chambers 104, 105 and 107, each housing a susceptor 106 to hold a substrate 130 during processing, and a showerhead 108 (comprising a fluid distribution system) to distribute one or more reactants to a surface of substrate 130. Reactor system 150 may include a direct plasma source 175 incorporated within any of chambers 104, 105 or 107 and/or a remote plasma source 170 coupled to any of chambers 104, 105 or 107. Multiple deposition and/or etching processes may be carried out in a single reaction chamber 104 and/or various processes may be carried out in separate reaction chambers 104, 105 and/or 107. Moreover, any methods or portions thereof disclosed herein may be carried out in a single reactor system 150 or a plurality of reactor systems configured for the specific process or portion of the method thereof.

For simplicity, precursor and/or reactant sources and carrier/purge gas sources are shown coupled to a single reaction chamber 104, however, it should be understood that reactant sources and carrier/purge gases for separate processes may be coupled to respective reaction chambers for those specific processes.

In an example, reactant (or co-reactant) source vessels 110, 112, 113, 114, 140, 142, 144, 164 and/or a carrier or purge gas source vessel 154, may be fluidly coupled to reaction chamber 104 via respective lines 116, 118, 119, 120, 141, 143, 145, 168 and 160, and respective valves or controllers 122, 123, 125, 126, 146, 147, 148, 166 and 158.

In an example, precursor and/or reactant gases may be contained in the above noted vessels and may be applied to substrate 130 in a reaction chamber during processing. For example, first vapor phase precursor 121 may be contained in vessel 113, second vapor phase precursor 124, third vapor phase precursor 115 may be contained in vessel 110, fourth vapor phase precursor 117 may be contained in vessel 112, may be contained in vessel 114, oxygen source 132 may be contained in vessel 140, fifth vapor phase precursor 134 may be contained in vessel 142, sixth vapor phase precursor 133 may be contained in vessel 144, seventh vapor phase precursor 162 may be contained in vessel 164, purge and/or carrier gas may be contained in vessel 156 and/or other materials from respective source vessels can be applied to substrate 130 in reaction chamber 104.

In some examples, first vapor phase precursor 121 and fifth vapor phase precursor 134 may be the same precursor and may be contained in a same vessel (e.g., both first vapor phase precursor 121 and fifth vapor phase precursor 134 may be contained in vessel 113 or vessel 142). In some examples, second vapor phase precursor 124 and sixth vapor phase precursor 133 may be the same precursor and may be contained in a same vessel (e.g., both second vapor phase precursor 124 and sixth vapor phase precursor 133 may be contained in vessel 114 or vessel 144).

In an example, carrier or purge gas 156 from gas source vessel 154 may be an inert gas and can be flowed to and through the reaction chamber (e.g. reaction chamber 104) to remove any excess reactant or other undesired materials from reaction chamber 104. System 150 can also comprise a vacuum source (e.g., vacuum source 128) fluidly coupled to the reaction chamber, which can be configured to evacuate reactants, a purge gas, or other materials out of the reaction chamber. Carrier or purge gas 156 may comprise argon, helium, neon, krypton, nitrogen and/or xenon, or the like, or combination thereof.

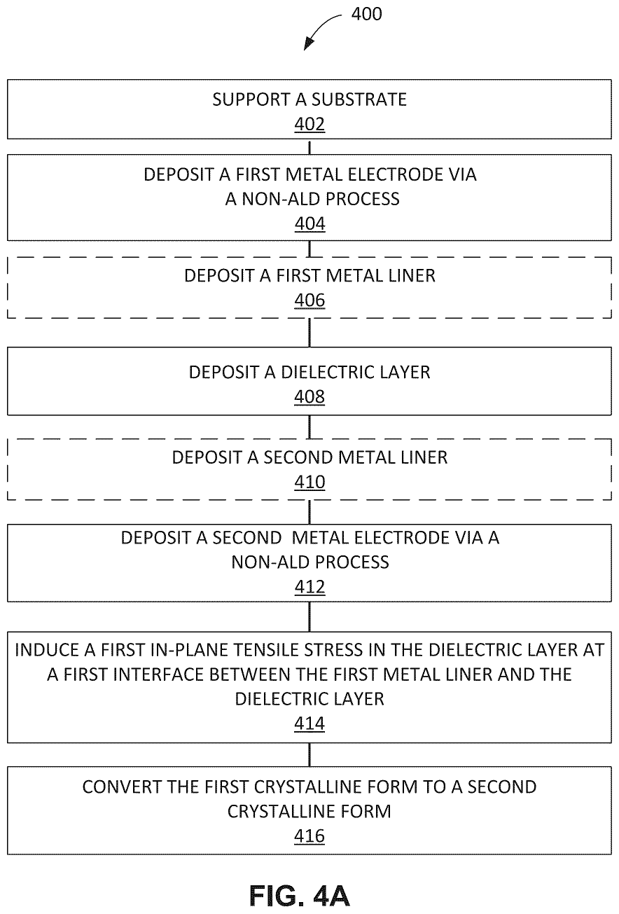

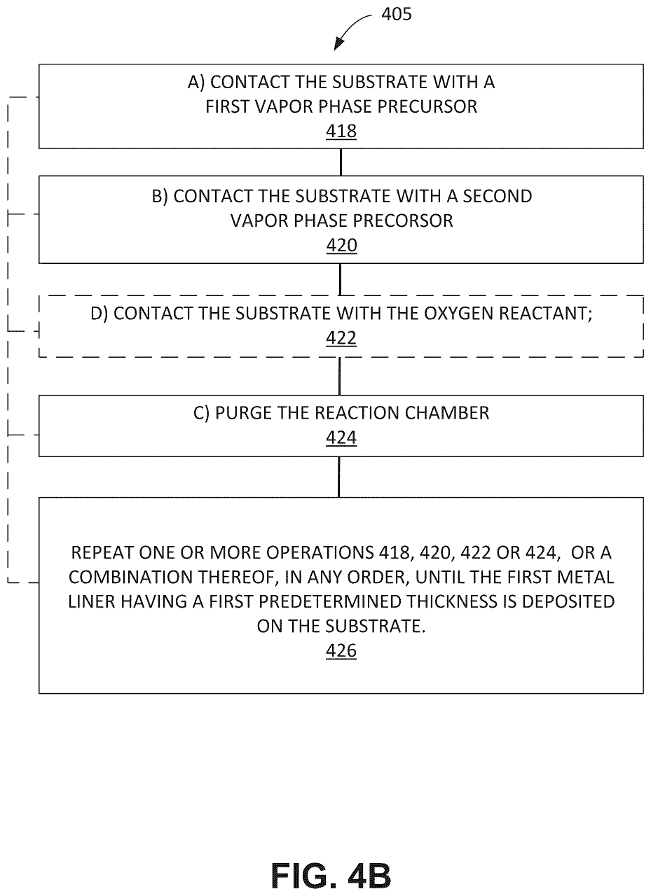

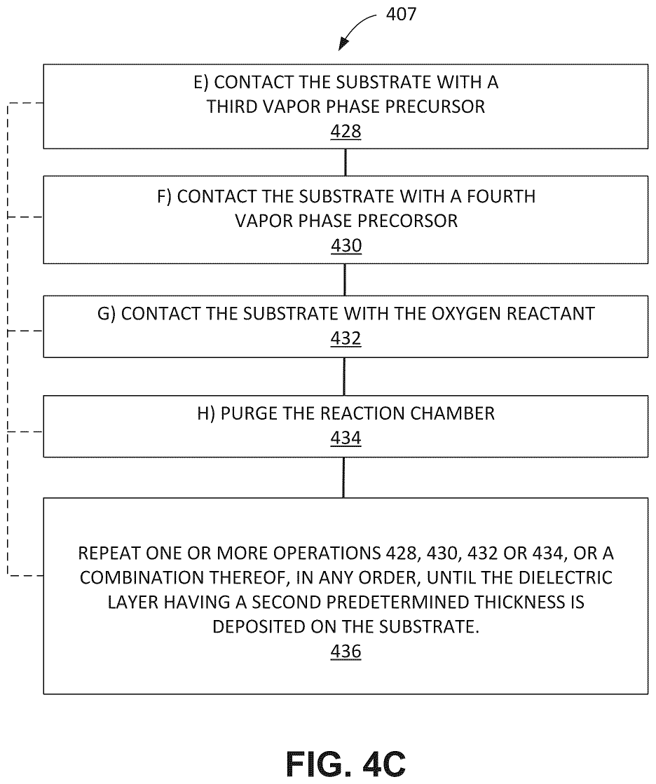

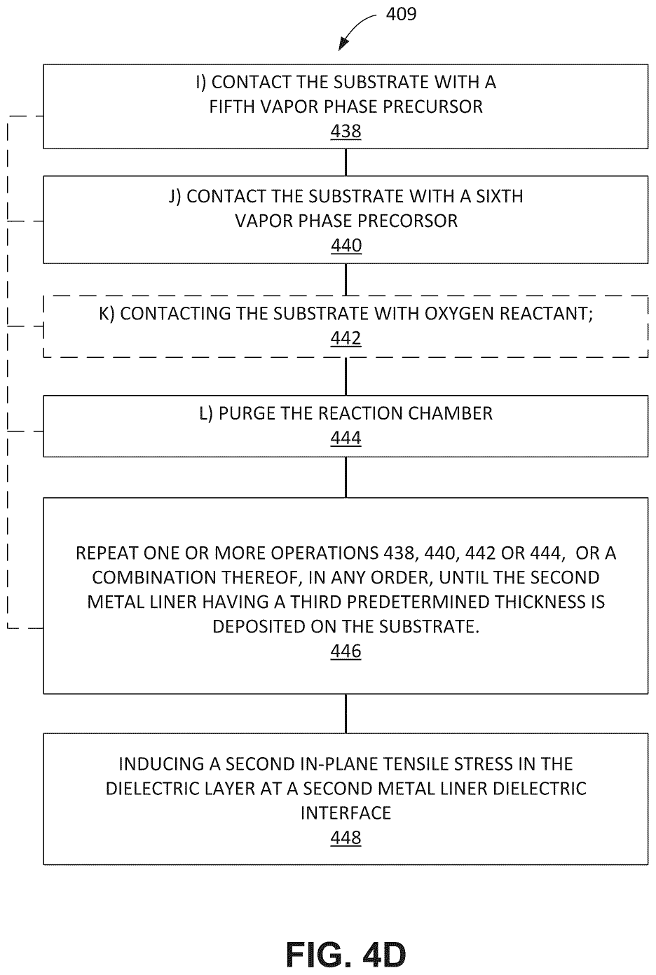

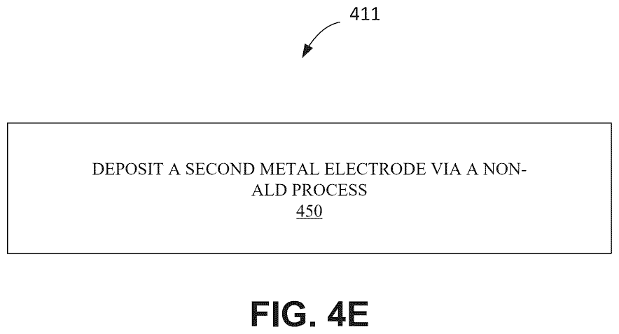

In an example, controller 152 can be configured to perform various functions and/or steps as described herein. Controller 152 can include one or more microprocessors, memory elements, and/or switching elements to perform the various functions. Although illustrated as a single unit, controller 152 can alternatively comprise multiple devices. By way of example, controller 152 can be used to control gas flow (e.g., by monitoring flow rates and controlling valves 122, 123, 125, 126, 146, 147, 148, 158 and/or 166), motors, showerhead 108, remote plasma source 170, heaters, cooling devices and/or vacuum source 158 to execute various processes (e.g., processes 400, 405, 407, 409 and/or 411 shown in respective FIGS. 4A, 4B, 4C, 4D and/or 4E). Further, when a system includes two or more reaction chambers, as described in more detail below, the two or more reaction chambers can be coupled to the same/shared controller.

“Composite film” as used herein refers to a film consisting of different material layers that remain substantially distinct. The layers may serve specific purposes and contribute to the overall properties of the film. Diffusion may occur between adjacent layers, allowing chemicals or substances to move across the interfaces and to become incorporated into adjacent film. Such diffusion may be intentional or unintentional.

In an example, system 150 may be configured to execute a series of deposition processes including non-atomic layer deposition (non-ALD) and atomic layer deposition (ALD) cyclic deposition sub-cycles to fabricate a multi-layered or composite film on substrate 130. In some examples the non-atomic layer deposition processes may be performed outside of system 150.

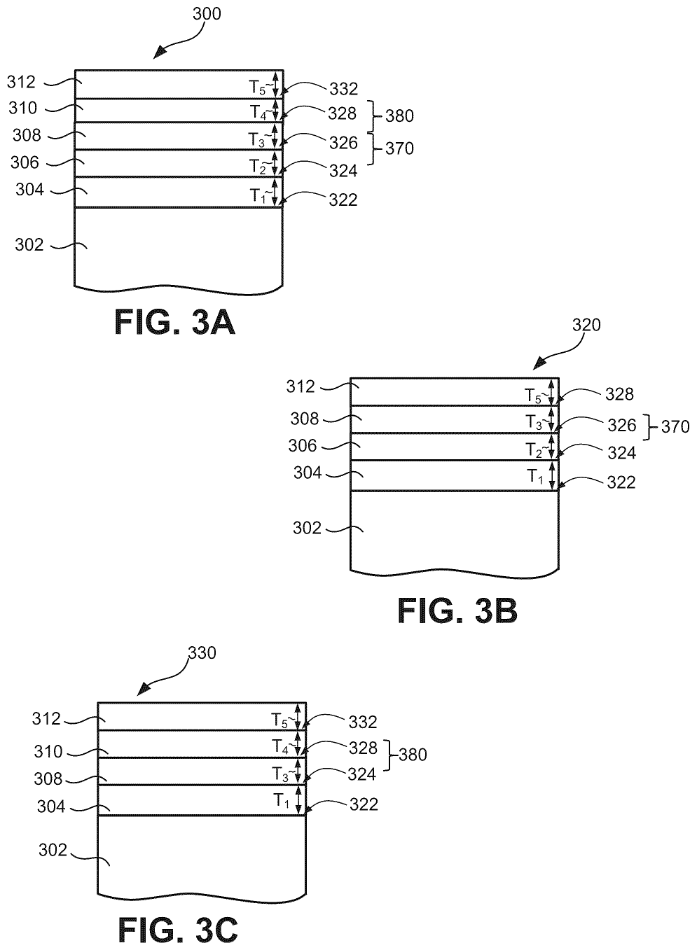

The composite film may be formed of a bottom conductive electrode, a bottom metal liner in contact with the bottom conductive electrode, a dielectric layer in contact with the bottom metal liner, a top metal liner in contact with the dielectric layer opposite the bottom metal liner, and a top conductive electrode in contact with the top metal liner. In some embodiments, the composite film may have the bottom conductive electrode and top conductive electrode and only a top metal liner or a bottom metal liner (see FIGS. 3A-3C).

The process begins with the deposition of a bottom metal electrode onto the substrate using non-atomic layer deposition (non-ALD) techniques. Given the bottom metal electrode thickness (e.g., 5-30 nm) compared to the thickness of other layers such as liner and dielectric layers (on the order of 5-100 angstroms) deposition of the bottom metal electrode by atomic layer deposition (ALD) may require considerable time having a greater negative impact on throughput than other layers in the composite film. To reduce this negative impact on throughput the bottom metal electrode may be deposited using a faster processing method such as chemical vapor deposition (CVD) or physical vapor deposition (PVD), reserving high-precision deposition techniques like ALD for the thinner liner and dielectric layers.

In some examples, a bottom metal liner is formed over the electrode using a cyclic-ALD process. This allows for precise control over the thickness and composition of the liner material. A dielectric layer may then be deposited in contact with the bottom metal liner using another cyclic-ALD process, providing in-plane tensile stress at the interface between the bottom metal liner and the dielectric layer. Fabrication of the composite film may continue with the deposition of a top metal liner via an additional cyclic-ALD process deposited in contact with the dielectric layer, providing in-plane tensile stress at the interface between the top metal liner and the dielectric layer. Finally, a top metal electrode may be applied over the top metal liner. Similar to the bottom metal electrode, the top metal electrode can also be deposited using faster non-ALD techniques due to its thickness and the lack of necessity for high precision.

This approach to layer deposition leverages the advantages of both non-ALD and cyclic-ALD processes, enabling the fabrication of a composite film with tailored electrical characteristics suitable for advanced electronic applications. The use of high precision ALD is reserved for the dielectric layer, thin top metal liner and/or bottom metal liner which may contact the dielectric layer, enabling the imparting of an in-plane stress at the liner-dielectric interfaces.

In an example, the composite film described herein may be incorporated into or form a portion of a variety of semiconductor devices such as a Metal-Insulator-Metal (MIM) structure, a Metal-Ferroelectric-Metal (MFM) structure, a Ferroelectric Random Access Memory (FeRAM) structure, a Ferroelectric Field-Effect Transistor (FeFET) structure, a Dynamic Random-Access Memory (DRAM) structure, a Resistive Random-Access Memory (ReRAM) structure or an Embedded Dynamic Random-Access Memory (eDRAM) structure, or a combination thereof.

In an example, the ALD processes for depositing the above noted composite film may be referred to as a “super cycle” and may comprise a plurality of sub-cycles. A “cyclic ALD sub-cycle” may be referred to herein interchangeably as a “cyclic ALD process.” A “non-ALD sub-cycle” may be referred to herein interchangeably as a “non-ALD process.”

For example, the super-cycle may include a sub-cycle comprising a first non-Atomic Layer Deposition (non-ALD) process wherein a first metal electrode may be deposited by a non-ALD process on substrate 130.

In an example, the super-cycle may include another sub-cycle to deposit a bottom metal liner on the first metal electrode. This bottom metal liner sub-cycle may comprise an ALD cyclic deposition process wherein a first vapor phase precursor 121 and a second vapor phase precursor 124 may contact the substrate 130 depositing a bottom metal liner on the substrate 130. In some examples, the bottom metal liner may comprise a metal nitride such as titanium nitride or tantalum nitride. In some examples, the bottom metal liner may comprise a metal oxynitride such as titanium oxynitride. Where the bottom metal liner comprises a metal oxynitride, the bottom metal liner sub-cycle may include contacting substrate 130 with oxygen source 132 in addition to first vapor phase precursor 121 and a second vapor phase precursor 124.

In the bottom metal liner sub-cycle, depositing the metal nitride or metal oxynitride liner layer on substrate 130 may comprise pulsing first vapor phase precursor 121 from reactant source vessel 113 to reaction chamber 104 via showerhead 108. Second vapor phase precursor 124 may be pulsed with or separately from first vapor phase precursor 121 from reactant source vessel 114 to reaction chamber 104 via showerhead 108. Where the bottom metal liner comprises a metal oxynitride, oxygen source 132 may be pulsed with or separately from first vapor phase precursor 121 and/or second vapor phase precursor 124 from source vessel 140 to reaction chamber 104 via showerhead 108. As first vapor phase precursor 121, second vapor phase precursor 124 and optionally oxygen source 132 contact substrate 130 the bottom metal liner comprising metal nitride or metal oxynitride may form on substrate 130. In some examples, the bottom metal liner may form on a surface of the bottom conductive electrode layer. In some examples, a bottom metal liner is not part of the composite film and therefor the bottom metal liner sub-cycle is not performed as a part of ALD super-cycle.

The reaction chamber 104 may be purged with a purge gas 156 from vessel 154 between one or more pulses of first vapor phase precursor 121, second vapor phase precursor 124 and optionally oxygen source 132. Chamber 104 may be purged between one or more deposition sub-cycles. The bottom metal liner deposition sub-cycle (or portions thereof) may be repeated until a desired thickness of the bottom metal liner is reached.

The super-cycle may include a sub-cycle to deposit a dielectric layer may comprise a variety of materials including but not limited to a metal oxide, metal silicate, and/or a doped metal oxide or doped metal silicate. In this dielectric layer sub-cycle, third vapor phase precursor 115, a fourth vapor phase precursor 117 and an oxygen source 132 may contact the substrate 130 depositing a dielectric layer.

In the dielectric layer sub-cycle, depositing the dielectric layer on substrate 130 may comprise pulsing third vapor phase precursor 115 from reactant source vessel 110 to reaction chamber 104 via showerhead 108. Fourth vapor phase precursor 117 may be pulsed with or separately from third vapor phase precursor 115 from reactant source vessel 112 to reaction chamber 104 via showerhead 108. Oxygen source 132 may be pulsed with or separately from third vapor phase precursor 115 and/or fourth vapor phase precursor 117 from source vessel 140 to reaction chamber 104 via showerhead 108. As oxygen source 132, third vapor phase precursor 115 and fourth vapor phase precursor 117 contact substrate 130 a dielectric layer may form on substrate 130. In some examples, the dielectric layer may form on a surface of the bottom metal liner. In some examples, the dielectric layer may form on a surface of the bottom metal electrode. The reaction chamber 104 may be purged with a purge gas 156 from vessel 154 between one or more pulses of oxygen source 132, third vapor phase precursor 115, fourth vapor phase precursor 117 and/or between one or more deposition sub-cycles. The first cyclic deposition process (or portions thereof) may be repeated until a desired thickness of the dielectric layer is reached.

In certain examples, the super-cycle may include a sub-cycle to deposit a top metal liner. This top metal liner sub-cycle may comprise an ALD cyclic deposition process wherein a fifth vapor phase precursor 134 and a sixth vapor phase precursor 133 may contact the substrate 130 depositing a top metal liner on the substrate 130. In some examples, the top metal liner may comprise a metal nitride such as titanium nitride or tantalum nitride. In some examples, the top metal liner may comprise a metal oxynitride such as titanium oxynitride. Where the top metal liner comprises a metal oxynitride the top metal liner sub-cycle may include contacting substrate 130 with oxygen source 132 in addition to fifth vapor phase precursor 134 and a sixth vapor phase precursor 133.

In the top metal liner sub-cycle, depositing the metal nitride or metal oxynitride liner layer on substrate 130 may comprise pulsing fifth vapor phase precursor 134 from reactant source vessel 140 to reaction chamber 104 via showerhead 108. Sixth vapor phase precursor 133 may be pulsed with or separately from fifth vapor phase precursor 134 from reactant source vessel 144 to reaction chamber 104 via showerhead 108. Where the bottom metal liner comprises a metal oxynitride, oxygen source 132 may be pulsed with or separately from fifth vapor phase precursor 134 and/or sixth vapor phase precursor 133 from source vessel 140 to reaction chamber 104 via showerhead 108. As fifth vapor phase precursor 134, sixth vapor phase precursor 133 and optionally oxygen source 132 contact substrate 130 the top metal liner comprising metal nitride or metal oxynitride may form on substrate 130. In some examples, the top metal liner may form on a surface of the dielectric layer. In some examples, a top metal liner is not part of the composite film and therefor the top metal liner sub-cycle is not performed as a part of the ALD super-cycle.

The reaction chamber 104 may be purged with a purge gas 156 from vessel 154 between one or more pulses of fifth vapor phase precursor 134, sixth vapor phase precursor 133 and optionally oxygen source 132. Chamber 104 may be purged between one or more deposition sub-cycles. The top metal liner deposition sub-cycle (or portions thereof) may be repeated until a desired thickness of the top metal liner is reached.

In certain examples, substrate 130 may be exposed to a transformation treatment. “Transformation treatment” herein refers to exposing a material on substrate 130 to a chemical and/or energy treatment so as to impact the material by transforming its crystalline form (e.g., converting a portion of a material layer having an amorphous solid form to a crystalline orthorhombic phase, or a crystalline tetragonal phase, or a combination thereof).

Such a transformation treatment may comprise exposing the substrate 130 to a rapid thermal anneal (RTA) treatment, an anneal treatment, a plasma treatment, treatment with ozone, ultraviolet light treatment, an oxidizing agent exposure, a nitridation agent exposure, a reducing agent exposure, an inert gas exposure, an electric field exposure or ultraviolet light exposure, or a combination thereof.

In an example, transformation treatment may be performed by exposing the substrate to the seventh vapor phase precursor 162 may comprise a transformation treatment agent stored in vessel 164. Such transformation treatment agent may comprise any of a variety of reactants, inert gases, nitrogen sources, hydrogen sources, oxygen sources, a source of species to be used in plasma treatment, or the like.

Chamber 104 may be purged with purge gas 156 between any one or more of the above-described transformation treatments, bottom metal liner sub-cycles, dielectric layer sub-cycles, and/or top metal liner sub-cycles.

In an example, the bottom metal liner, dielectric layer and/or top metal liner may be deposited in the same chamber (e.g., chamber 104) or may be deposited in different chambers. Similarly, the transformation treatment may be performed in the same chamber (e.g., chamber 104) or in a different chamber. Moreover, each layer may be deposited separately or in applications other than as in the above-described composite film and claimed subject matter is not limited in this regard. For example, the above-described layers may be useful in device applications other than for MIM and MFM devices.

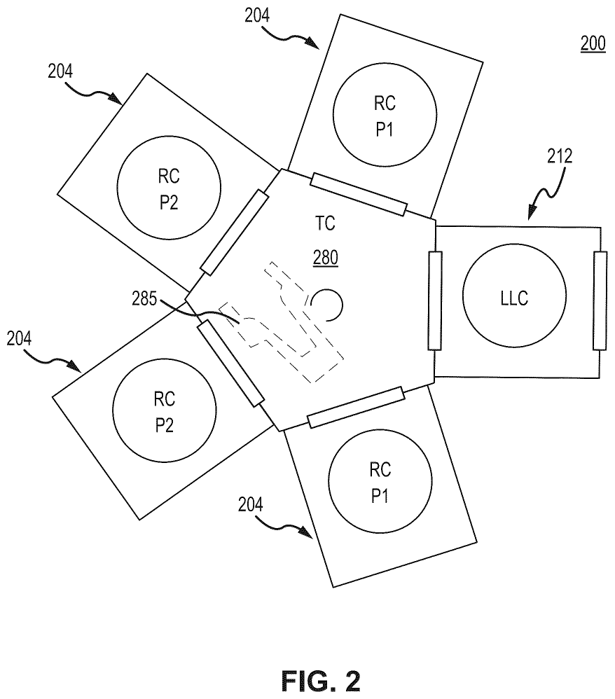

In some examples, a reactor system (e.g., reactor system 150) can comprise multiple reaction chambers. For example, in reactor system 200, shown in FIG. 2, a number of reaction chambers 204 (each of which can be an example of any of reaction chambers 104, 105, and/or 107 in FIG. 1) can be disposed around and/or coupled to a transfer chamber 280 comprising a transfer tool 285 for transferring substrates between reaction chambers 204. Substrates can be transferred from a load lock chamber 212 and between reaction chambers 204 (e.g., through transfer chamber 280). For example, a substrate 130 can be disposed in different chambers for different steps of a semiconductor manufacturing process. In other words, the bottom metal liner deposition sub-cycle, the dielectric layer deposition sub-cycle, and/or the top metal liner deposition sub-cycle may each be performed in the same or different chambers.

FIGS. 3A-3C illustrate various composite films fabricated in accordance with examples of the present technology.

FIG. 3A illustrates a device 300 in accordance with examples of the disclosure. Device 300 may comprise a MIM or MFM device and/or a device incorporated into other specific device architectures, such as a Ferroelectric Random Access Memory (FeRAM) structure, a Ferroelectric Field-Effect Transistor (FeFET) structure, a Dynamic Random-Access Memory (DRAM) structure, a Resistive Random-Access Memory (ReRAM) structure or an Embedded Dynamic Random-Access Memory (eDRAM) structure, and/or any of a variety of other devices and claimed subject matter is not limited in this regard.

In an example, device 300 includes a substrate 302, a bottom metal electrode 304, a bottom metal liner 306, a dielectric layer 308, a top metal liner 310, and a top metal electrode 312. In an example, bottom metal liner 306 comprises one or more layers of material deposited by one or more cyclic ALD processes on substrate. In an example, top metal liner 310 comprises one or more layers of material deposited by one or more cyclic ALD processes on a substrate.

In an example, substrate 302 can be or include any of the substrate materials described hereinabove.

In an example, a bottom metal electrode 304 may be disposed on surface 322 of substrate 302. Bottom metal electrode 304 may be deposited by a non-ALD process such as by CVD or PVD and may comprise any of a variety of conductive materials such as but not limited to titanium nitride (TiN), titanium oxynitride (TiOxNy), aluminum (Al), copper (Cu), tungsten (W), cobalt (Co), nickel (Ni), molybdenum (Mo), indium (In), gallium (Ga), ruthenium (Ru), titanium (Ti), tantalum (Ta), vanadium (V), silicon carbide (SiC). In an example, the thickness T1 may be less than 50 nanometers (nm), or about 1 nm to about 50 nm, or about 2 nm to about 45 nm, or about 3 nm to about 40 nm, or about 4 nm to about 40 nm, or about 5 nm to about 30 nm, or any appropriate thickness (“about” in this context means +/−5 nm).

In an example, a bottom metal liner 306 may be disposed on surface 324 of bottom metal electrode 304. Bottom metal liner 306 may be deposited by an ALD process according to various examples disclosed herein such as the bottom metal liner sub-cycle described with respect to FIG. 1. In an example, bottom metal liner 306 may comprise any of a variety of materials such as but not limited to titanium nitride (TiN), titanium oxynitride (TiOxNy), and tantalum nitride (TaN). Bottom metal liner 306 may comprise the same material as a bottom metal electrode 304. In some examples, bottom metal liner 306 may comprise a different material from bottom metal electrode 304. In an example, the thickness T2 of bottom metal liner 306 may be less than 100 angstrom (Å), or about 5 Å to about 100 Å, or about 5 Å to about 75 Å, or about 5 Å to about 50 Å, or about 5 Å to about 30 Å, or about 5 Å to about 25 Å, or any appropriate thickness (“about” in this context means +/−10 Å).

In an example, dielectric layer 308 may be disposed on surface 326 of bottom metal liner 306. Dielectric layer 308 may be deposited by an ALD process according to various examples disclosed herein such as the dielectric layer sub-cycle described with respect to FIG. 1. Dielectric layer 308 may be a high-k and/or ferroelectric material. In some examples, the dielectric layer may be a metallic oxide having a dielectric constant greater than about 7. In some examples, dielectric layer 308 may comprise one or more of hafnium oxide (HfO2), hafnium zirconium oxide (HZO), zirconium oxide (ZrO2), titanium oxide (TiOx), hafnium silicate (HfSiOx), aluminum oxide (Al2O3), lanthanum oxide (La2O3), germanium oxide (GeOx), cerium oxide (CeOx), yttrium oxide (YxOy), tantalum oxide (TaxOy), scandium oxide (ScxOy), bismuth oxide (BixOy), one or more of the preceding materials may be doped with yttrium oxide, and/or mixtures/laminates comprising one or more such layers.

In an example, an interface 370 between the bottom metal liner 306 and dielectric layer 308 may experience in-plane tensile stress sufficient to convert or transform a first crystalline form of dielectric layer 308 to a second crystalline form of dielectric layer 308. Such conversion (as discussed in greater detail below) increases the non-centrosymetricity of the dielectric layer so as to increase the dielectric layer's dielectric constant and/or ferroelectric properties. In certain embodiments, doping the dielectric layer as described above may increase the dielectric layer's ability to convert from a first crystalline form to a second crystalline form and thus improve non-centrosymetricity. In an example, the thickness T3 of dielectric layer 308 may be less than 100 angstrom (Å), or about 10 Å to about 150 Å, or about 15 Å to about 125 Å, or about 20 Å to about 100 Å, or about 5 Å to about 50 Å, or about 5 Å to about 30 Å, or any appropriate thickness (“about” in this context means +/−10 Å).

In an example, top metal liner 310 may be deposited on the dielectric layer 308 surface 328. Top metal liner 310 may be deposited by an ALD process according to various examples disclosed herein such as the top metal liner sub-cycle described with respect to FIG. 1. In an example, top metal liner 306 may comprise any of a variety of materials such as but not limited to titanium nitride (TiN), titanium oxynitride (TiOxNy), and tantalum nitride (TaN).

In an example, an interface 380 between the top metal liner 310 and dielectric layer 308 may experience in-plane tensile stress sufficient to convert or transform a first crystalline form of dielectric layer 308 to a second crystalline form of dielectric layer 308. Such conversion (as discussed in greater detail below) increases the non-centrosymetricity of the dielectric layer so as to increase the dielectric layer's dielectric constant and/or ferroelectric properties. In certain embodiments, doping the dielectric layer as described above may increase the dielectric layer's ability to convert from a first crystalline form to a second crystalline form and thus improve non-centrosymetricity.

In an example, the presence of a top metal liner 310 interface 380 and a bottom metal liner 306 interface 370 at the dielectric may compound the in-plane tensile stress and may therefore increase the dielectric layer's propensity to convert from a first crystalline form to a second crystalline form. In an example, the thickness T4 of top metal liner 310 may be less than 100 angstrom (Å), or about 5 Å to about 100 Å, or about 5 Å to about 75 Å, or about 5 Å to about 50 Å, or about 5 Å to about 30 Å, or about 5 Å to about 25 Å, or any appropriate thickness (“about” in this context means +/−10 Å).

In an example, a top metal electrode 312 may be disposed on surface 332 of top metal liner 310. Top metal electrode 312 may be deposited by a non-ALD process such as by CVD or PVD and may comprise any of a variety of conductive materials such as but not limited to titanium nitride (TiN), titanium oxynitride (TiOxNy), aluminum (Al), copper (Cu), tungsten (W), cobalt (Co), nickel (Ni), molybdenum (Mo), indium (In), gallium (Ga), ruthenium (Ru), titanium (Ti), tantalum (Ta), vanadium (V), or silicon carbide (SiC), or a combination thereof. In an example, the thickness T5 may be less than 50 nanometers (nm), or about 1 nm to about 50 nm, or about 2 nm to about 45 nm, or about 3 nm to about 40 nm, or about 4 nm to about 40 nm, or about 5 nm to about 30 nm, or any appropriate thickness (“about” in this context means +/−5 nm).

FIG. 3B illustrates a device 320 in accordance with examples of the disclosure. Device 320 may be similar to device 300 described with reference to FIG. 3A and may comprise a MIM or MFM device and/or a device incorporated into other specific device architectures, such as a Ferroelectric Random Access Memory (FeRAM) structure, a Ferroelectric Field-Effect Transistor (FeFET) structure, a Dynamic Random-Access Memory (DRAM) structure, a Resistive Random-Access Memory (ReRAM) structure or an Embedded Dynamic Random-Access Memory (eDRAM) structure, and/or any of a variety of other devices and claimed subject matter is not limited in this regard.

In an example, device 320 includes a substrate 302, a bottom metal electrode 304, a bottom metal liner 306, a dielectric layer 308, and a top metal electrode 312.

In an example, substrate 302 can be or include any of the substrate materials described hereinabove.

In an example, a bottom metal electrode 304 may be disposed on surface 322 of substrate 302. Bottom metal electrode 304 may be deposited by a non-ALD process such as by CVD or PVD and may comprise any of a variety of conductive materials such as but not limited to titanium nitride (TiN), titanium oxynitride (TiOxNy), aluminum (Al), copper (Cu), tungsten (W), cobalt (Co), nickel (Ni), molybdenum (Mo), indium (In), gallium (Ga), ruthenium (Ru), titanium (Ti), tantalum (Ta), vanadium (V), silicon carbide (SiC). In an example, the thickness T1 may be less than 50 nanometers (nm), or about 1 nm to about 50 nm, or about 2 nm to about 45 nm, or about 3 nm to about 40 nm, or about 4 nm to about 40 nm, or about 5 nm to about 30 nm, or any appropriate thickness (“about” in this context means +/−5 nm).

In an example, a bottom metal liner 306 may be disposed on surface 324 of bottom metal electrode 304. Bottom metal liner 306 may be deposited by an ALD process according to various examples disclosed herein such as the bottom metal liner sub-cycle described with respect to FIG. 1. In an example, bottom metal liner 306 may comprise any of a variety of materials such as but not limited to titanium nitride (TiN), titanium oxynitride (TiOxNy), and tantalum nitride (TaN). Bottom metal liner 306 may comprise the same material as a bottom metal electrode 304. In some examples, bottom metal liner 306 may comprise a different material from bottom metal electrode 304. In an example, the thickness T2 of bottom metal liner 306 may be less than 100 angstrom (Å), or about 5 Å to about 100 Å, or about 5 Å to about 75 Å, or about 5 Å to about 50 Å, or about 5 Å to about 30 Å, or about 5 Å to about 25 Å, or any appropriate thickness (“about” in this context means +/−10 Å).

In an example, dielectric layer 308 may be disposed on surface 326 of bottom metal liner 306. Dielectric layer 308 may be deposited by an ALD process according to various examples disclosed herein such as the dielectric layer sub-cycle described with respect to FIG. 1. Dielectric layer 308 may be a high-k and/or ferroelectric material, for example, a metallic oxide having a dielectric constant greater than about 7. In some embodiments, the high-k material has a dielectric constant higher than the dielectric constant of silicon oxide. Exemplary high-k materials include one or more of hafnium oxide hafnium oxide (HfO2), hafnium zirconium oxide (HZO), zirconium oxide (ZrO2), titanium oxide (TiOx), hafnium silicate (HfSiOx), aluminum oxide (Al2O3), lanthanum oxide (La2O3), germanium oxide (GeOx), cerium oxide (CeOx), yttrium oxide (YxOy), tantalum oxide (TaxOy), scandium oxide (ScxOy), bismuth oxide (BixOy), one or more of the preceding high-k materials may be doped with yttrium oxide, and/or mixtures/laminates comprising one or more such layers.

In an example, the thickness T3 may be less than 100 angstrom (Å), or about 50 Å to about 100 Å, or about 25 Å to about 75 Å, or about 15 Å to about 50 Å, or about 5 Å to about 30 Å, or any appropriate thickness (“about” in this context means +/−10 Å).

In an example, an interface 370 between the bottom metal liner 306 and dielectric layer 308 may experience in-plane tensile stress sufficient to convert or transform a first crystalline form of dielectric layer 308 to a second crystalline form of dielectric layer 308. Such conversion (as discussed in greater detail below) increases the non-centrosymetricity of the dielectric layer so as to increase the dielectric layer's dielectric constant and/or ferroelectric properties. In certain embodiments, doping the dielectric layer as described above may increase the dielectric layer's ability to convert from a first crystalline form to a second crystalline form and thus improve non-centrosymetricity.

In an example, a top metal electrode 312 may be disposed on surface 328 of dielectric layer 308. Top metal electrode 312 may be deposited by a non-ALD process such as by CVD or PVD and may comprise any of a variety of conductive materials such as but not limited to titanium nitride (TiN), titanium oxynitride (TiOxNy), aluminum (Al), copper (Cu), tungsten (W), cobalt (Co), nickel (Ni), molybdenum (Mo), indium (In), gallium (Ga), ruthenium (Ru), titanium (Ti), tantalum (Ta), vanadium (V), silicon carbide (SiC). In an example, the thickness T5 may be less than 50 nanometers (nm), or about 1 nm to about 50 nm, or about 2 nm to about 45 nm, or about 3 nm to about 40 nm, or about 4 nm to about 40 nm, or about 5 nm to about 30 nm, or any appropriate thickness (“about” in this context means +/−5 nm).

FIG. 3C illustrates a device 330 in accordance with examples of the disclosure. Device 300 may comprise a MIM or MFM device and/or a device incorporated into other specific device architectures, such as a Ferroelectric Random Access Memory (FeRAM) structure, a Ferroelectric Field-Effect Transistor (FeFET) structure, a Dynamic Random-Access Memory (DRAM) structure, a Resistive Random-Access Memory (ReRAM) structure or an Embedded Dynamic Random-Access Memory (eDRAM) structure, and/or any of a variety of other devices and claimed subject matter is not limited in this regard.

In an example, device 300 includes a substrate 302, a bottom metal electrode 304, a dielectric layer 308, a top metal liner 310, and a top metal electrode 312.

In an example, substrate 302 can be or include any of the substrate materials described hereinabove.

In an example, a bottom metal electrode 304 may be disposed on surface 322 of substrate 302. Bottom metal electrode 304 may be deposited by a non-ALD process such as by CVD or PVD and may comprise any of a variety of conductive materials such as but not limited to titanium nitride (TiN), titanium oxynitride (TiOxNy), aluminum (Al), copper (Cu), tungsten (W), cobalt (Co), nickel (Ni), molybdenum (Mo), indium (In), gallium (Ga), ruthenium (Ru), titanium (Ti), tantalum (Ta), vanadium (V), silicon carbide (SiC). In an example, the thickness T1 may be less than 50 nanometers (nm), or about 1 nm to about 50 nm, or about 2 nm to about 45 nm, or about 3 nm to about 40 nm, or about 4 nm to about 40 nm, or about 5 nm to about 30 nm, or any appropriate thickness (“about” in this context means +/−5 nm).

In an example, dielectric layer 308 may be disposed on surface 324 of bottom metal electrode 304. Dielectric layer 308 may be deposited by an ALD process according to various examples disclosed herein such as the dielectric layer sub-cycle described with respect to FIG. 1. Dielectric layer 308 may be a high-k and/or ferroelectric material, for example, a metallic oxide having a dielectric constant greater than about 7. In some embodiments, the high-k material has a dielectric constant higher than the dielectric constant of silicon oxide. Exemplary high-k materials include one or more of hafnium oxide (HfO2), tantalum oxide (Ta2O5), hafnium zirconium oxide (HZO), zirconium oxide (ZrO2), titanium oxide (TiO2), hafnium silicate (HfSiOx), aluminum oxide (Al2O3), lanthanum oxide (La2O3), and mixtures/laminates comprising one or more such layers. In an example, the thickness T3 may be less than 100 angstrom (Å), or about 50 Å to about 100 Å, or about 25 Å to about 75 Å, or about 15 Å to about 50 Å, or about 5 Å to about 30 Å, or any appropriate thickness (“about” in this context means +/−10 Å).

In an example, top metal liner 310 may be deposited on the dielectric layer 308 surface 328. Top metal liner 310 may be deposited by an ALD process according to various examples disclosed herein such as the top metal liner sub-cycle described with respect to FIG. 1. In an example, top metal liner 306 may comprise any of a variety of materials such as but not limited to titanium nitride (TiN), titanium oxynitride (TiOxNy), and tantalum nitride (TaN). In an example, the thickness T4 of top metal liner 310 may be less than 100 angstrom (Å), or about 5 Å to about 100 Å, or about 5 Å to about 75 Å, or about 5 Å to about 50 Å, or about 5 Å to about 30 Å, or about 5 Å to about 25 Å, or any appropriate thickness (“about” in this context means +/−10 Å).

In an example, an interface 380 between the top metal liner 310 and dielectric layer 308 may experience in-plane tensile stress sufficient to convert or transform a first crystalline form of dielectric layer 308 to a second crystalline form of dielectric layer 308. Such conversion (as discussed in greater detail below) increases the non-centrosymetricity of the dielectric layer so as to increase the dielectric layer's dielectric constant and/or ferroelectric properties. In certain embodiments, doping the dielectric layer as described above may increase the dielectric layer's ability to convert from a first crystalline form to a second crystalline form and thus improve non-centrosymetricity.

In an example, a top metal electrode 312 may be disposed on surface 332 of top metal liner 310. Top metal electrode 312 may be deposited by a non-ALD process such as by CVD or PVD and may comprise any of a variety of conductive materials such as but not limited to titanium nitride (TiN), titanium oxynitride (TiOxNy), aluminum (Al), copper (Cu), tungsten (W), cobalt (Co), nickel (Ni), molybdenum (Mo), indium (In), gallium (Ga), ruthenium (Ru), titanium (Ti), tantalum (Ta), vanadium (V), silicon carbide (SiC). In an example, the thickness T5 may be less than 50 nanometers (nm), or about 1 nm to about 50 nm, or about 2 nm to about 45 nm, or about 3 nm to about 40 nm, or about 4 nm to about 40 nm, or about 5 nm to about 30 nm, or any appropriate thickness (“about” in this context means +/−5 nm).

FIG. 4A illustrates an example process 400 for depositing a composite film (e.g., device 300, see FIG. 3A). Although the example process 400 depicts a particular sequence of operations, the sequence may be altered without departing from the scope of the present disclosure.

According to some examples, process 400 may begin at operation 402 where a substrate (e.g., substrate 130, see FIG. 1) may be supported, for example, in a reaction chamber. The chamber may be configured to carry out a non-ALD process. In some examples, process 400 may be performed in a plurality of chambers, for example, a first chamber 104 (see FIG. 1) for executing ALD processes and a second chamber 105 (see FIG. 1) for carrying out non-ALD processes. In the current example, the substrate 130 may be supported in chamber 105 initially where operation 404 may be executed to deposit the first metal electrode via a non-ALD process and subsequently transferred to chamber 104 in which one or more cyclic ALD processes (e.g., cyclic ALD sub-cycles discussed above) may be carried out. In other examples, both ALD and non-ALD processes may be carried out in the same chamber.

In an example, process 400 may proceed to operation 404 where a first metal electrode (top or bottom) may be deposited on the substrate 130 via a first non-Atomic Layer Deposition (non-ALD) process.

In an example, process 400 may proceed to operation 406 where a first metal liner (e.g., top metal liner 310 or bottom metal liner 306, see FIGS. 3A, 3B, and 3C) may be deposited. Deposition of the first metal liner may be optional as indicated with a dashed line. Deposition of the first metal liner may be executed via a first cyclic ALD process 405 (see FIG. 4B). In some examples, the first metal liner may be deposited in physical contact with an already deposited dielectric layer or may be deposited prior to deposition of a dielectric layer.

In an example, process 400 may proceed to a second cyclic deposition process 407 (see FIG. 4C) at operation 408 where a dielectric layer (e.g., dielectric layer 308, see FIGS. 3A, 3B, and 3C) may be deposited. The dielectric layer may be deposited in physical contact with the first metal liner or a second metal liner (see FIGS. 3A and 3B). In an example, the dielectric layer may come into physical contact with the first metal liner layer and/or a second metal liner (see FIGS. 3A and 3C) subsequent to deposition.

In an example, the dielectric layer may be deposited in physical and/or electrical contact with a first metal electrode or a second metal electrode (e.g., top metal electrode 312, or bottom metal electrode 304, see FIGS. 3A, 3B and 3C). In an example, the dielectric layer may come into physical and/or electrical contact with the first metal liner electrode and/or a second metal electrode (e.g., top metal liner 310 or bottom metal liner 306, see FIGS. 3A, 3B and 3C) subsequent to deposition. In an example, the dielectric layer may comprise a high-k dielectric and/or ferroelectric material. In an example, some portion of the dielectric layer may be amorphous and/or may comprise one or more crystalline features or structures such as orthorhombic structures and/or tetragonal structures. The as-deposited dielectric layer may have a first crystalline form including an amorphous solid, orthorhombic structures and/or tetragonal structures.

In an example, process 400 may proceed to operation 410 where a second metal liner (e.g., top metal liner 310 or bottom metal liner 306, see FIGS. 3A, 3B, and 3C) may be deposited. Deposition of the second metal liner may be optional as indicated with a dashed line. Deposition of the second metal liner may be executed via a third cyclic ALD process 409 (see FIG. 4D). In some examples, the second metal liner may be deposited in physical contact with an already deposited dielectric layer or may be deposited prior to deposition of a dielectric layer.

The composite film may comprise a single metal liner in contact with the dielectric layer (e.g., FIGS. 3B and 3C) or may comprise two metal liners in contact with the dielectric layer on opposing sides (e.g., FIG. 3A). For simplicity, deposition of the first metal liner and/or deposition of the second metal liner may each be described herein as optional. However, the composite film comprises at least one of the first metal liner or the second metal liner, or a combination thereof.

In an example, the first metal liner and/or the second metal liner may be deposited at a temperature in the range of about 150° C.-600° C., or about 200° C.-500° C., or about 250° C.-450° C., or any appropriate temperature (“about” in this context means +/−50° C.).

In an example, process 400 may proceed to operation 412 wherein a second metal electrode may be deposited by a non-ALD process. Deposition of the second metal electrode may be executed via a second non-ALD process 411 (see FIG. 4E)

In an example, process 400 may proceed to operation 414 wherein a first in-plane tensile stress may be induced in the dielectric layer at a first interface between the first metal liner and the dielectric layer. The first or second metal electrodes and/or first and second metal liners may each contribute to in-plane tensile stress and, depending upon the configuration of the composite film, may interface physically with the dielectric layer. However, in some embodiments the tensile stress induced by the first metal liner may be greater than the tensile stress induced by, for example, the first metal electrode and/or a second metal electrode, and/or a second metal liner (e.g., wherein the second metal liner is a bottom metal liner).

In an example, process 400 may proceed to operation 416 wherein the first crystalline form may be converted to a second crystalline form, responsive to the first in-plane tensile stress.

In some examples, the first crystalline form is in a first non-centrosymmetric state and the second crystalline form is in a second non-centrosymmetric state. The second non-centrosymmetric state may comprise greater non-centrosymmetricity than the first non-centrosymmetric state. In an example, converting the first crystalline form comprising a first non-centrosymmetric state to a second crystalline form comprising a second non-centrosymmetric state may increase a dielectric constant of the dielectric layer by about 10%-100%, or about 20%-100%, or about 35%-100%, or about 50%-100%, or about 75%-100%, or any appropriate percentage (“about” in this context means +/−15%).

In an example, converting the first crystalline form comprising a first non-centrosymmetric state to a second crystalline form comprising a second non-centrosymmetric state may increase the ferroelectricity of the dielectric layer.

In some examples, the dielectric layer in the first crystalline form may comprise at least a first portion that is in an amorphous phase. The first portion of the dielectric layer that is in the amorphous phase may be converted to a crystalline orthorhombic phase when converted to the second crystalline form.

In some examples, the dielectric layer in the first crystalline form may comprise at least a second portion that is in a crystalline tetragonal phase. The second portion of the dielectric layer that is in the crystalline tetragonal phase may be converted to a crystalline orthorhombic phase when converted to the second crystalline form.

In certain examples, the first crystalline form comprises a first percentage of a crystalline orthorhombic phase and the second crystalline form comprises a second percentage of the crystalline orthorhombic phase, wherein the second percentage is greater than the first percentage.

In particular examples, operation 416, converting the first crystalline form to the second crystalline form, may be accomplished responsive to the in-plane tensile stress alone or in combination with one or more of a variety of additional transformation treatments. For example, the first crystalline form may be converted to a second crystalline form responsive to the in-plane tensile stress and due to exposure of the substrate or various layers of the composite film making up devices 300, 320 and 330 (see FIGS. 3A-3C) to a transformation treatment.

In an example, a transformation treatment may comprise, exposing the substrate, or any layer of the composite film to one or more of: a rapid thermal anneal (RTA), an anneal, a plasma exposure, an ozone exposure, an oxidizing agent exposure, a nitridation agent exposure, a reducing agent exposure, an inert gas exposure, an electric field exposure, or ultraviolet light exposure, or a combination thereof.

In an example, transformation treatment may impart mechanical, thermal and/or chemical energy to the dielectric layer or one or both metal liner layers impacting the first crystalline form of the dielectric layer aiding in the conversion of the first crystalline form to a second crystalline form induced by the in-plane tensile stress. In some embodiments, the transformation treatment may increase in-plane tensile strain at the interface between the dielectric layer and the first and/or second metal liner layers.

In a certain example, during operation 408, a transformation treatment may be applied to the dielectric layer or one or both metal liner layers (e.g., bottom metal liner 306, dielectric layer 308, and/or top metal liner 310, see FIGS. 3A, 3B, 3C). The transformation treatment may comprise heating the dielectric layer or one or both metal liner layers to a temperature in the range of about 150° C. to 700° C., or about 200° C.-650° C., or about 250° C.-600° C., or any appropriate temperature range (“about” in this context means +/−15%).

FIG. 4B illustrates an example first cyclic ALD process 405 for depositing the first metal liner. The first metal liner may comprise any of a variety of materials. In an example, the first metal liner may comprise any material that does not have a major lattice mismatch in comparison to the dielectric layer. Materials for a first metal liner layer may be selected based on a material having similar crystal phases to the dielectric material used in the dielectric layer (e.g., dielectric layer 308, see FIG. 3A). Additionally, the first metal liner layer material should have a higher Gibbs Free energy of oxide/nitride formation when compared to the metal oxide/nitride dielectric layer. In an example, the first metal liner layer may comprise titanium nitride (TiN), tantalum nitride (TaN), and/or titanium oxynitride (TiOxNy).

In an example, first cyclic ALD process 405 may start with operation 418 wherein the substrate may be contacted with a first vapor phase precursor 121 (see FIG. 1). In an example, the first vapor phase precursor may be a metal containing precursor and may comprise at least one of titanium tetrachloride (TiCl4), titanium tetraiodide (TiI4), titanium tetrabromide (TiBr3), tantalum pentachloride (TaCl5), or the like, or a combination thereof.

In an example, the first cyclic ALD process 405 may proceed to operation 420 wherein the substrate may be contacted with a second vapor phase precursor 124 (see FIG. 1). The second vapor phase precursor may be a nitrogen containing precursor and may comprise at least one of ammonia (NH3), hydrazine (N2H4), a hydrazine derivative, an alkyl-hydrazine, tertbutylhydrazine (C4H9N2H3), methylhydrazine (CH3NHNH2), dimethylhydrazine ((CH3)2N2H2), phenylhydrazine, tert-butylamine, isobutylamine, tert-pentylamine, N2 plasma, N2/H2 plasma, NH3 plasma, an excited species of nitrogen, nitrogen ions, nitrogen radicals, or any combination thereof.

Where the first metal liner layer comprises TiOxNy, the first cyclic ALD process 405 may proceed to an alternate (indicated with dashed lines) operation 422 wherein the substrate may be contacted with an oxygen reactant in some examples. In an example, the oxygen reactant may comprise at least one of: water (H2O), hydrogen peroxide (H2O2), oxygen (O2), ozone (O3), nitrous oxide (N2O), nitric oxide (NO), nitrogen dioxide (NO2), or an oxygen plasma, or a combination thereof.

In an example, first cyclic ALD process 405 may proceed to operation 424 wherein the reaction chamber may be purged (e.g., by pulsing a purge gas 156 into the chamber 104, see FIG. 1). As indicated by dashed lines, purging operation 424 may be executed at any juncture in first cyclic deposition process 405 (e.g., before, after and/or between operations 418, 420, 422, and/or before or after first cyclic deposition process 405). Excess chemical and reaction byproduct, if any, may be removed from reaction chamber by purging. Purging gas (e.g., purge gas 156, see FIG. 1), is preferably any inert as, such as, without limitation, argon (Ar), nitrogen, (N2), or helium (He).

In an example, first cyclic ALD process 405 may proceed to operation 426 wherein one or more operations 418, 420, 422 and/or 424, or a combination thereof, may be repeated any number of times, in any order, until the first metal liner reaches a first predetermined thickness is deposited on the substrate. In an example, the first predetermined thickness may be less than 100 angstrom (Å), or about 5 Å to about 100 Å, or about 5 Å to about 75 Å, or about 5 Å to about 50 Å, or about 5 Å to about 30 Å, or about 5 Å to about 25 Å, or any appropriate thickness (“about” in this context means +/−10 Å).

FIG. 4C illustrates an example second cyclic ALD process 407 for depositing the dielectric layer. The dielectric layer may comprise any of a variety of materials described herein. Second cyclic ALD process 407 may begin at operation 428 by contacting the substrate with a third vapor phase precursor 115 (see FIG. 1). In an example, third vapor phase precursor may comprise a metal organic, silicide or halide, such as, but not limited to tetrakis (dimethylamino) hafnium, tetrakis (diethylamino) hafnium, tetrakis (ethylmethylamino) hafnium, HfCl4, HfBr4, and HfI4,tetrakis (dimethylamino) zirconium (TDMAZ), tetrakis (dimethylamido) titanium (TDMAT), hafnium tetra-tert-butoxide (Hf(OC(CH3)3)4), tetrakis-ethylmethylaminosilane (Si(N(CH3)—(C2H5))4), trimethylaluminum (TMA), tris (N,N′-diisopropylacetamidinato) yttrium (III) (Y(DPfAMD)3), Ge(NMe2)4, Ge(OnBu)4, tris (N,N′-diisopropylacetamidinato) cerium (III) (Ce(DPfAMD)3), tris (N,N′-diisopropylacetamidinato) yttrium (III) (Y(DPfAMD)3), tantalum pentachloride (TaCl5), scandium chloride (ScCl3), bismuth chloride (BiCl3), or the like or combinations thereof.

In an example, second cyclic ALD process 407 may proceed to operation 430 wherein an additional precursor may contact the substrate, for example if the dielectric layer is a mixed metal oxide or silicide such as hafnium zirconium oxide or hafnium silicate (HfSiOx) the substrate may be contacted with a fourth vapor phase precursor 117 (see FIG. 1). In an example, the fourth vapor phase precursor may comprise at least one of, tetrakis (dimethylamino) zirconium, tetrakis (diethylamino) zirconium, tetrakis-ethylmethylaminosilane (Si(N(CH3)—(C2H5))4) or tetrakis (ethylmethylamino) zirconium, or any combination thereof.

In an example, second cyclic ALD process 407 may proceed to operation 432 by contacting the substrate with an oxygen reactant 132 (see FIG. 1). In an example, the oxygen reactant may comprise one or more of H2O, H2O2, O2, O3, N2O, NO, NO2 or an oxygen plasma.

In an example, second cyclic ALD process 407 may proceed to operation 434 wherein the reaction chamber may be purged (e.g., by pulsing a purge gas 156 into the chamber 104, see FIG. 1). As indicated by dashed lines, purging operation 434 may be executed at any juncture in second cyclic deposition process 407 (e.g., before, after and/or between operations 428, 430, 432, and/or before or after second cyclic deposition process 407). Excess chemical and reaction byproduct, if any, may be removed from reaction chamber by purging. Purging gas (e.g., purge gas 156, see FIG. 1), is preferably any inert as, such as, without limitation, argon (Ar), nitrogen, (N2), or helium (He).

In an example, second cyclic ALD process 407 may proceed to operation 436 wherein one or more operations 428, 430, 432 and/or 434, or a combination thereof, may be repeated any number of times, in any order, until the dielectric layer is deposited on the substrate and reaches a second predetermined thickness. The second predetermined thickness may be less than 100 angstrom (Å), or about 10 Å to about 150 Å, or about 15 Å to about 125 Å, or about 20 Å to about 100 Å, or about 5 Å to about 50 Å, or about 5 Å to about 30 Å, or any appropriate thickness (“about” in this context means +/−10 Å).

FIG. 4D illustrates an example third cyclic ALD process 409 for depositing the second metal liner. The second metal liner may comprise any of a variety of materials described herein, such as but not limited to titanium nitride (TiN), tantalum nitride (TaN), and/or titanium oxynitride (TiOxNy).

In an example, third cyclic ALD process 409 may start with operation 438 wherein the substrate may be contacted with a fifth vapor phase precursor 134 (see FIG. 1). In an example, the fifth vapor phase precursor may be a metal containing precursor and may comprise at least one of titanium tetrachloride (TiCl4), titanium tetraiodide (TiI4), titanium tetrabromide (TiBr3), tantalum pentachloride (TaCl5), or the like, or a combination thereof.

In an example, the third cyclic ALD process 409 may proceed to operation 440 wherein the substrate may be contacted with a sixth vapor phase precursor 133 (see FIG. 1). The sixth vapor phase precursor may be a nitrogen containing precursor and may comprise at least one of ammonia (NH3), hydrazine (N2H4), a hydrazine derivative, an alkyl-hydrazine, tertbutylhydrazine (C4H9N2H3), methylhydrazine (CH3NHNH2), dimethylhydrazine ((CH3)2N2H2), phenylhydrazine, tert-butylamine, isobutylamine, tert-pentylamine, N2 plasma, N2/H2 plasma, NH3 plasma, an excited species of nitrogen, nitrogen ions, nitrogen radicals, or any combination thereof.

In an example, the third liner layer may comprise TiOxNy. In such an example, the third cyclic ALD process 409 may proceed to an alternate (indicated with dashed lines) operation 442 wherein the substrate may be contacted with an oxygen reactant in some examples. In an example, the oxygen reactant may comprise at least one of: water (H2O), hydrogen peroxide (H2O2), oxygen (O2), ozone (O3), nitrous oxide (N2O), nitric oxide (NO), nitrogen dioxide (NO2), or an oxygen plasma, or a combination thereof.

In an example, third cyclic ALD process 405 may proceed to operation 444 wherein the reaction chamber may be purged (e.g., by pulsing a purge gas 156 into the chamber 104, see FIG. 1). As indicated by dashed lines, purging operation 444 may be executed at any juncture in third cyclic deposition process 409 (e.g., before, after and/or between operations 438, 440, 444, and/or before or after third cyclic deposition process 409). Excess chemical and reaction byproduct, if any, may be removed from reaction chamber by purging. Purging gas (e.g., purge gas 156, see FIG. 1), is preferably any inert as, such as, without limitation, argon (Ar), nitrogen, (N2), or helium (He).

In an example, third cyclic ALD process 409 may proceed to operation 446 wherein one or more operations 438, 440, 442 and/or 444, or a combination thereof, may be repeated any number of times, in any order, until the second metal liner is deposited on the substrate and reaches a third predetermined thickness. In an example, the third predetermined thickness may be less than 100 angstrom (Å), or about 5 Å to about 100 Å, or about 5 Å to about 75 Å, or about 5 Å to about 50 Å, or about 5 Å to about 30 Å, or about 5 Å to about 25 Å, or any appropriate thickness (“about” in this context means +/−10 Å).

Referring now to FIG. 4E illustrating a second non-ALD process 411 for depositing the second metal electrode (e.g., top metal electrode 312 or bottom metal electrode 304, see FIG. 3A). In an example, at operation 450, deposition of the second metal electrode is via a second non-Atomic Layer Deposition (non-ALD) process. The second metal electrode may comprise either a top metal electrode or a bottom metal electrode which may be in electrical communication with the dielectric layer and/or in physical contact with the dielectric layer. Further, the top or bottom metal electrode layer may be in contact with the first or second metal liners.

The second metal electrode may have a predetermined thickness. In an example, the thickness may be less than 50 nanometers (nm), or about 1 nm to about 50 nm, or about 2 nm to about 45 nm, or about 3 nm to about 40 nm, or about 4 nm to about 40 nm, or about 5 nm to about 30 nm, or any appropriate thickness (“about” in this context means +/−5 nm).

In an example, the first metal electrode comprises a bottom metal electrode and the first metal liner comprises a bottom metal liner, and wherein the depositing the first metal liner further comprises disposing the bottom metal liner in physical contact with the bottom metal electrode. In an example, the second metal electrode comprises a top metal electrode in physical contact with the dielectric layer.

Although exemplary examples of the present disclosure are set forth herein, it should be appreciated that the disclosure is not so limited. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A method for depositing a composite film, comprising:
supporting a substrate;
depositing a first metal electrode via a first non-Atomic Layer Deposition (non-ALD) process;
depositing a first metal liner, via a first cyclic ALD process;
depositing a dielectric layer via a second cyclic ALD process, the dielectric layer disposed in electrical communication with the first metal electrode and in physical contact with the first metal liner, wherein the dielectric layer comprises a first crystalline form;
inducing a first in-plane tensile stress in the dielectric layer at a first interface between the first metal liner and the dielectric layer; and
converting the first crystalline form to a second crystalline form, responsive to the first in-plane tensile stress.

2. The method of claim 1, wherein the dielectric layer is a high-k material or a ferroelectric material.

3. The method of claim 1, wherein the depositing the first metal liner is performed at a temperature in a range of 150° C.-600° C.

4. The method of claim 3, wherein the first metal liner is deposited on a surface of the dielectric layer.

5. The method of claim 1, wherein the first crystalline form is in a first non-centrosymmetric state and wherein the second crystalline form is in a second non-centrosymmetric state.

6. The method of claim 5, wherein the second non-centrosymmetric state comprises greater non-centrosymmetricity than the first non-centrosymmetric state.

7. The method of claim 5, wherein at least a portion of the first crystalline form is in an amorphous phase and the second crystalline form is in a crystalline orthorhombic phase or to a crystalline tetragonal phase, or a combination thereof.

8. The method of claim 5, wherein the first crystalline form comprises a first percentage of a crystalline orthorhombic phase and wherein the second crystalline form comprises a second percentage of the crystalline orthorhombic phase, wherein the second percentage is greater than the first percentage.

9. The method of claim 5, wherein the converting the first crystalline form to the second crystalline form further comprises heating the dielectric layer to a temperature in a range of 150° C. to 700° C.

10. The method of claim 1, further comprising exposing the substrate to one or more transformation treatments comprising at least one of a rapid thermal anneal, an anneal treatment, a plasma treatment, or exposure to ozone, or a combination thereof.

11. The method of claim 1, wherein the converting the first crystalline form to the second crystalline form further comprises exposing the substrate to a transformation treatment comprising at least one of a rapid thermal anneal (RTA), an anneal, a plasma exposure, an ozone exposure, an oxidizing agent exposure, a nitridation agent exposure, a reducing agent exposure, or an inert gas exposure, or a combination thereof.

12. The method of claim 5, wherein the converting the first crystalline form to the second crystalline form increases a dielectric constant of the dielectric layer by 10%-100%.

13. The method of claim 5, wherein the converting the first crystalline form to the second crystalline form increases a ferroelectricity of the dielectric layer.

14. The method of claim 1, wherein the non-ALD process comprises a chemical vapor deposition (CVD) or a physical vapor deposition (PVD) process.

15. The method of claim 1, wherein the tensile stress induced by the first metal liner is greater than the tensile stress induced by the first metal electrode.

16. The method of claim 1, wherein the first cyclic ALD process comprises:
a) contacting the substrate with a first vapor phase precursor;
b) contacting the substrate with a second vapor phase precursor;
c) purging the chamber; and
repeating one or more of operations a), b) or c), or a combination thereof, in any order, until the first metal liner having a first predetermined thickness is deposited on the substrate.

17. The method of claim 16, wherein the first vapor phase precursor comprises at least one of titanium tetrachloride (TiCl4), titanium tetraiodide (TiI4), titanium tetrabromide (TiBr3), tantalum pentachloride (TaCl5) or a combination thereof.

18. The method of claim 17, wherein the second vapor phase precursor comprises at least one of ammonia (NH3), hydrazine (N2H4), a hydrazine derivative, an alkyl-hydrazine, tertbutylhydrazine (C4H9N2H3), methylhydrazine (CH3NHNH2), dimethylhydrazine ((CH3)2N2H2), phenylhydrazine, tert-butylamine, isobutylamine, tert-pentylamine, N2 plasma, N2/H2 plasma, NH3 plasma, an excited species of nitrogen, nitrogen ions, nitrogen radicals, or a combination thereof.

19. The method of claim 18, wherein the first metal liner comprises titanium nitride (TiN) or tantulum nitride (TaN).

20. The method of claim 18, wherein the first cyclic ALD process further comprises:
d) contacting the substrate with an oxygen reactant; and
repeating one or more of operations a), b), c) or d), or a combination thereof, in any order, until the first metal liner having the first predetermined thickness is deposited on the substrate.

21. The method of claim 20, wherein the first metal liner comprises titanium oxynitride.

22. The method of claim 16, wherein the first metal electrode comprises a top metal electrode and the first metal liner comprises a top metal liner comprising a metal nitride, wherein the depositing the first metal liner, further comprises disposing the top metal liner in physical contact with the top metal electrode and depositing a second metal electrode via a second non-Atomic Layer Deposition (non-ALD) process, wherein the second metal electrode comprises a bottom metal electrode in physical contact with the dielectric layer.

23. The method of claim 22, wherein the bottom metal electrode and the top metal electrode are each less than 50 nanometers (nm) in thickness and wherein the top metal liner is less than 100 angstrom (Å) in thickness.

24. The method of claim 16, wherein the first metal electrode comprises a bottom metal electrode and the first metal liner comprises a bottom metal liner, and wherein the depositing the first metal liner further comprises disposing the bottom metal liner in physical contact with the bottom metal electrode.

25. The method of claim 24, further comprising depositing a second metal electrode via a second non-Atomic Layer Deposition (non-ALD) process, wherein the second metal electrode comprises a top metal electrode in physical contact with the dielectric layer.

26. The method of claim 25, wherein the bottom metal electrode and the top metal electrode are less than 50 nanometers (nm) in thickness and wherein the bottom metal liner is less than 100 angstrom (Å) in thickness.

27. The method of claim 16, wherein the second cyclic ALD process comprises:
e) contacting the substrate with a third vapor phase precursor;
f) contacting the substrate with a fourth vapor phase precursor;
g) contacting the substrate with an oxygen reactant;
h) purging the reaction chamber; and
repeating one or more operations e), f) g), or h) or any combination thereof, in any order, until the dielectric layer having a predetermined thickness is deposited on the substrate.

28. The method of claim 27, wherein the third vapor phase precursor comprises at least one of: tetrakis(dimethylamino)hafnium, tetrakis(diethylamino)hafnium, tetrakis(ethylmethylamino)hafnium, HfCl4, HfBr4, and HfI4, tetrakis(dimethylamino)zirconium (TDMAZ), tetrakis(dimethylamido)titanium (TDMAT), hafnium tetra-tert-butoxide (Hf(OC(CH3)3)4), tetrakis-ethylmethylaminosilane (Si(N(CH3)—(C2H5))4), trimethylaluminum (TMA), tris(N, N′-diisopropylacetamidinato) yttrium (III) (Y(DPfAMD)3), Ge(NMe2)4,Ge(OnBu)4, tris(N, N′-diisopropylacetamidinato)cerium (III) (Ce(DPfAMD)3), tris(N, N′-diisopropylacetamidinato)yttrium (III) (Y(DPfAMD)3), tantalum pentachloride (TaCl5), scandium chloride (ScCl3), bismuth chloride (BiCl3), or a combination thereof.

29. The method of claim 27, wherein the fourth vapor phase precursor comprises at least one of: tetrakis(dimethylamino)zirconium, tetrakis(diethylamino)zirconium, tetrakis-ethylmethylaminosilane (Si(N(CH3)—(C2H5))4) or tetrakis (ethylmethylamino) zirconium, or any combination thereof.

30. The method of claim 27, wherein the oxygen reactant is one or more of H2O, H2O2, O2, O3, N2O, NO, NO2 or an oxygen plasma.

31. The method of claim 27, wherein the dielectric layer comprises a dielectric material comprising at least one of: hafnium oxide (HfO2), hafnium zirconium oxide (HZO), zirconium oxide (ZrO2), titanium oxide (TiOx), hafnium silicate (HfSiOx), aluminum oxide (Al2O3), lanthanum oxide (La2O3), germanium oxide (GeOx), cerium oxide (CeOx), yttrium oxide (YxOy), tantalum oxide (TaxOy), scandium oxide (ScxOy), bismuth oxide (BixOy), one or more of the dielectric materials doped with yttrium oxide, or combinations thereof.

32. The method of claim 27, further comprising:
depositing a second metal liner via a third cyclic ALD process, wherein the second metal liner comprises a top metal liner in physical contact with the dielectric layer;
inducing a second in-plane tensile stress in the dielectric layer at a second interface between the top metal liner and the dielectric layer;
depositing a second metal electrode via a non-Atomic Layer Deposition (non-ALD) process, wherein the second metal electrode comprises a top metal electrode in physical contact with the top metal liner.

33. The method of claim 32, wherein the third cyclic ALD process comprises:
i) contacting the substrate with a fifth vapor phase precursor;
j) contacting the substrate with a sixth vapor phase precursor;
k) purging the reaction chamber; and
repeating one or more operations i), j) or k), or any combination thereof, in any order, until the second metal liner having a third predetermined thickness is deposited on the dielectric layer.

34. The method of claim 33, wherein the fifth vapor phase precursor comprises at least one of titanium tetrachloride (TiCl4), titanium tetraiodide (TiI4), titanium tetrabromide (TiBr3), tantalum pentachloride (TaCl5) or a combination thereof.

35. The method of claim 33, wherein the sixth vapor phase precursor comprises at least one of ammonia (NH3), hydrazine (N2H4), a hydrazine derivative, an alkyl-hydrazine, tertbutylhydrazine (C4H9N2H3), methylhydrazine (CH3NHNH2), dimethylhydrazine ((CH3)2N2H2), phenylhydrazine, tert-butylamine, isobutylamine, tert-pentylamine, N2 plasma, N2/H2 plasma, NH3 plasma, an excited species of nitrogen, nitrogen ions, nitrogen radicals, or any combination thereof.

36. The method of claim 33, wherein the second metal liner comprises titanium nitride (TiN) or tantulum nitride (TaN).

37. The method of claim 33, wherein the third cyclic ALD process further comprises:
l) contacting the substrate with the oxygen reactant; and
repeating one or more operations i), j), k) or l), or a combination thereof, in any order, until the second metal liner having the third predetermined thickness is deposited on the dielectric layer.

38. The method of claim 37, wherein the second metal liner comprises titanium oxynitride (TiON).

39. The method of claim 33, wherein the bottom metal electrode and the top metal electrode are less than 50 nanometers (nm) in thickness and wherein the top metal liner and the bottom metal liner are less than 100 angstrom (Å) in thickness.

40. The method of claim 1, wherein the composite film, forms at least a portion of a Metal-Insulator-Metal (MIM) structure, a Metal-Ferroelectric-Metal (MFM) structure, a Ferroelectric Random Access Memory (FeRAM) structure, a Ferroelectric Field-Effect Transistor (FeFET) structure, a Dynamic Random-Access Memory (DRAM) structure, a Resistive Random-Access Memory (ReRAM) structure or an Embedded Dynamic Random-Access Memory (eDRAM) structure, or a combination thereof.
